(19) United States
(12) Patent Application Publication
(10) Pub. No.: US 2026/0206608 A1
(43) Pub. Date: Jul. 16, 2026

(54) INK JETTING A PROTECTIVE MATERIAL LAYER ON AN INTEGRATED CIRCUIT DIE PAD BEFORE LASER DRILLING IN A PANEL LEVEL PACKAGING PROCESS

(71) Applicant: STMicroelectronics International N.V., Geneva (CH)

(72) Inventors: Shei Meng LOO, Singapore (SG); David GANI, Choa Chu Kang (SG)

(73) Assignee: STMicroelectronics International N.V., Geneva (CH)

(21) Appl. No.: 19/409,248

(22) Filed: Dec. 4, 2025

Related U.S. Application Data
(60) Provisional application No. 63/744,526, filed on Jan. 13, 2025.

(51) Int. Cl. H10W 70/08; H10P 58/00; H10W 70/00; H10W 70/05; H10W 70/63; H10W 70/66; H10W 74/01; H10W 74/10

(52) U.S. Cl. CPC H10W 70/08; H10P 58/00; H10W 70/093; H10W 70/095; H10W 70/099; H10W 70/63; H10W 70/66; H10W 74/016; H10W 74/121

(57) ABSTRACT

A wafer includes integrated circuit areas, where each integrated circuit area has at least one conductive die pad. A passivation layer is provided over the conductive die pads. A die pad opening is formed extending through the passivation layer at each die pad. Use a jet printing process, a dot of conductive ink is deposited at each die pad opening to form a die pad protection layer covering an upper surface of each conductive die pad. A film layer covers the passivation layer and the die pad protection layer at each die pad. Using a laser drilling process, a via opening if formed extending through the film layer at each die pad to reach the die pad protection layer. The die pad protection layer protects the die pad during the laser drilling.

### CROSS REFERENCE TO RELATED APPLICATIONS

This application claims priority to United States Provisional Application for Patent No. 63/744,526, filed January 13, 2025, the content of which is incorporated by reference.

### TECHNICAL FIELD

The present invention generally relates to a process for packaging integrated circuits and, in particular, to a panel level packaging process utilizing an ink jetted conductive material layer to protect pads of an integrated circuit die from incurring damage during a subsequent laser drilling operation.

### BACKGROUND

Reference is made to United States Patent Application Publication No. 2022/0285256, incorporated herein by reference, as exemplary of a prior art panel level packaging method for producing packaged integrated circuits.

### SUMMARY

In an embodiment, a method comprises: providing a wafer including a plurality of integrated circuit areas, said wafer including, for each integrated circuit area, a plurality of electrically conductive die pads, and further including a passivation layer over the plurality of electrically conductive die pads; forming a die pad opening extending through the passivation layer at each electrically conductive die pad of the plurality of electrically conductive die pads; jet printing a conductive ink at each die pad opening to form a die pad protection layer covering an upper surface of each electrically conductive die pad of the plurality of electrically conductive die pads; providing a film layer covering the passivation layer and the die pad protection layer at each electrically conductive die pad of the plurality of electrically conductive die pads; and laser drilling a via opening through the film layer to reach the die pad protection layer at each electrically conductive die pad of the plurality of electrically conductive die pads.

The die pad protection layer protects the underlying electrically conductive die pad from being damaged by the laser energy used to drill the via opening in the film layer. The via opening formed by the laser drilling operation may, for example extend partially into, without passing through, the die pad protection layer.

In an embodiment, an integrated circuit die comprises: a semiconductor substrate with integrated circuitry; an interconnection layer with a plurality of electrically conductive die pads electrically coupled to the integrated circuitry; a die passivation layer covering an upper surface of the interconnection layer, said die passivation layer only partially covering each electrically conductive die pad of the plurality of electrically conductive die pads; a dot of conductive ink at an upper surface of each electrically conductive die pad of the plurality of electrically conductive die pads, said dot forming a die pad protection layer within a die pad opening in the die passivation layer; and a film layer covering the die passivation layer and the die pad protection layer over each electrically conductive die pad of the plurality of electrically conductive die pads, wherein the film layer includes via openings extending through the film layer to reach the die pad protection layer at each electrically conductive die pad of the plurality of electrically conductive die pads.

The underlying electrically conductive die pad is protected from damage by the die pad protection layer.

### BRIEF DESCRIPTION OF THE DRAWINGS

For a better understanding of the embodiments, reference will now be made by way of example only to the accompanying figures in which:

FIG. 1 shows a cross-sectional view of an integrated circuit package; and

FIGS. 2A-2S illustrate steps in a process for forming the package of FIG. 1

### DETAILED DESCRIPTION

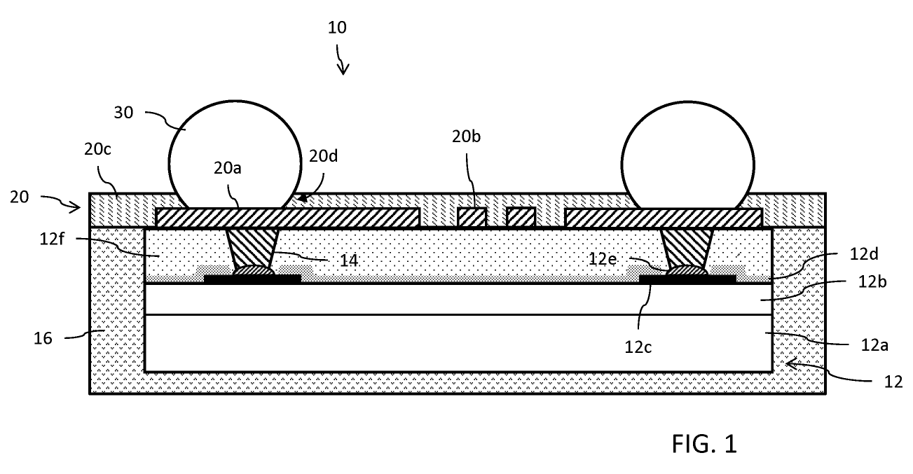

Reference is made to FIG. 1 which shows a cross-sectional view of an integrated circuit package 10. The package 10 secures and encloses an integrated circuit (IC) die 12 having a semiconductor (for example, silicon) substrate 12a with integrated circuitry (not explicitly shown), an interconnection layer 12b with electrically conductive die pads 12c (the interconnection layer 12b including interconnection structures (electrically conductive lines, vias, etc., not explicitly shown but well-known to those skilled in the art) for electrically connecting the die pads 12c to the integrated circuitry of the substrate 12a), a die passivation layer 12d which covers the upper surface of the interconnection layer 12b and partially covers the die pads 12c, an electrically conductive die pad protection layer 12e in contact with an upper surface of each die pad 12c and positioned within die pad openings in the die passivation layer 12d at each die pad 12c, and a dielectric film layer 12f which covers the die passivation layer 12d. This dielectric film layer 12f may comprise an insulating film layer (such as, for example, of the build-up film type known in the semiconductor manufacturing art).

Vias 14 are provided at the upper surface of the dielectric film layer 12f which extend through openings in the dielectric film layer 12f thickness to make physical contact with and electrical connection to the die pad protection layer 12e positioned on the upper surface of the die pads 12c. The die pad protection layer 12e provides a covering which protects the die pads 12c during the laser drilling operation to punch through the thickness of the dielectric film layer 12f when forming the openings within which the vias 14 are provided. In the absence of the die pad protection layer 12e on the upper surface of the die pads 12c, there is a not insignificant risk that the laser drilling operation will cause damage to the die pads 12c which can have adverse effects such as increasing the impedance of the via connection to the die pad. The die pad protection layer 12e is made of a material (for example, copper (Cu), gold (Au) or silver (Ag), or alloys thereof) having a sufficient thickness (for example, in a range of 1 to 3 µm) that is resistant to laser damaging while supporting a low impedance interconnection between the via 14 and the die pads 12. The selection of a suitable material for the die pad protection layer 12e is also made dependent on the material being applied (for example, through use of an ink jet printing technique for controlled dispensing of a conductive ink) in a manner which does not adversely increase the overall processing time for manufacturing the IC die 12 or the package 10.

The side edges of the dielectric film layer 12f are aligned with the side edges of the interconnection layer 12b and substrate 12a.

The IC die 12 may be manufactured using wafer scale processing techniques where a semiconductor wafer (including multiple instances of the integrated circuitry), with an overlying interconnection layer, passivation layer, die pad protection layer and dielectric film layer, is processed at wafer scale, including the formation of at least the openings for the vias 14, and subjected to a singulation operation which dices the processed wafer at scribing or cutting lines to produce a plurality of singulated IC dies, one of which, referenced 12 herein, being shown in the figure.

A part of the processing operation for making singulated IC dies may include a thinning of the wafer substrate from the back side. This back side thinning is performed at wafer scale prior to singulation.

The IC die 12 is at least laterally encapsulated by an encapsulation body 16 (and may further be encapsulated on the back side of the substrate 12a as shown). The upper surface of the encapsulation body 16 is coplanar with the upper surface of the dielectric film layer 12f at the front side of the interconnection layer 12b, and the lower surface of the second encapsulation body 16 may be coplanar with or offset from – as shown in the FIGURE– the lower (i.e., back side) surface of the substrate 12a of the IC die 12.

The package structure of the IC die 12 with the lateral encapsulation body 16 may be manufactured using panel scale processing techniques where a plurality of IC dies 12 are secured to a panel carrier and placed within a mold cavity. The material for forming the second encapsulation 16 is then injected into the mold cavity and cured. A subsequent singulation operation can be performed to dice the panel and separate the IC dies 12 encapsulated by the second encapsulation body 16 from each other to form the packages 10.

A redistribution layer (RDL) 20 is provided over the dielectric film layer 12f. This redistribution layer 20 includes electrically conductive lines 20a and package pads 20b formed by selectively plating an electrically conductive material (such as copper). The electrically conductive lines 20a and package pads 20b are at least laterally encapsulated by, and perhaps further covered by (as shown), an encapsulation body 20c. This encapsulation body 20c may be provided, for example, through a molding process or through a film lamination process.

Bonding balls 30 (or pillars) are provided at the package pads 20b. The encapsulation body 20c includes contact openings 20d exposing an upper surface of the package pads 20b where the bonding balls 30 are installed. The package 10 may be mounted to a substrate, such as a printed circuit board, for example, using the bonding balls 30.

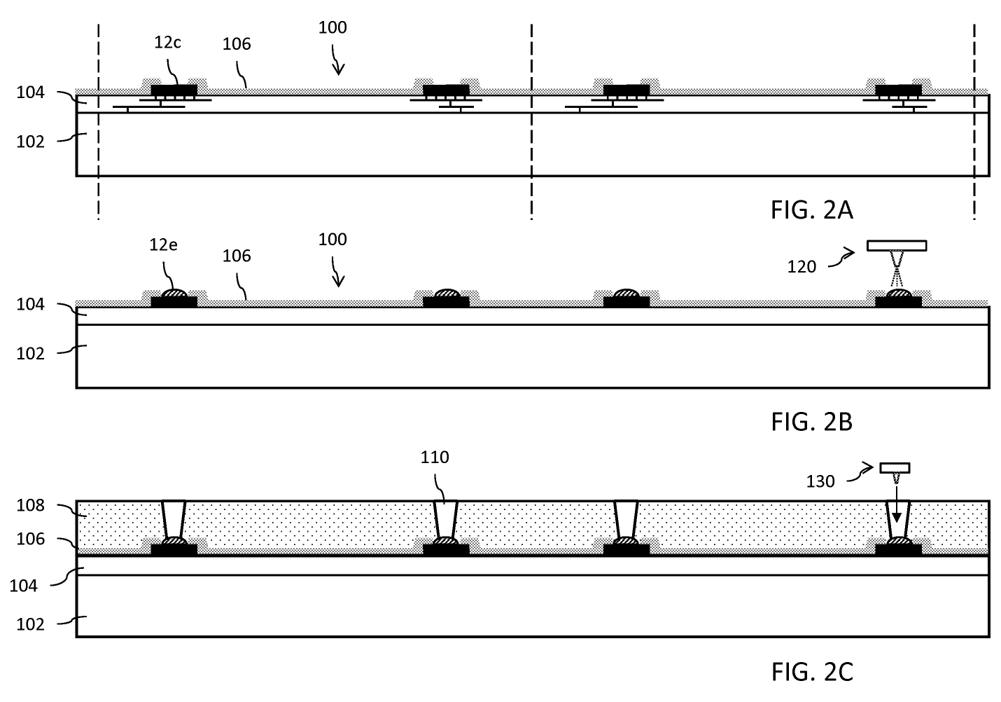

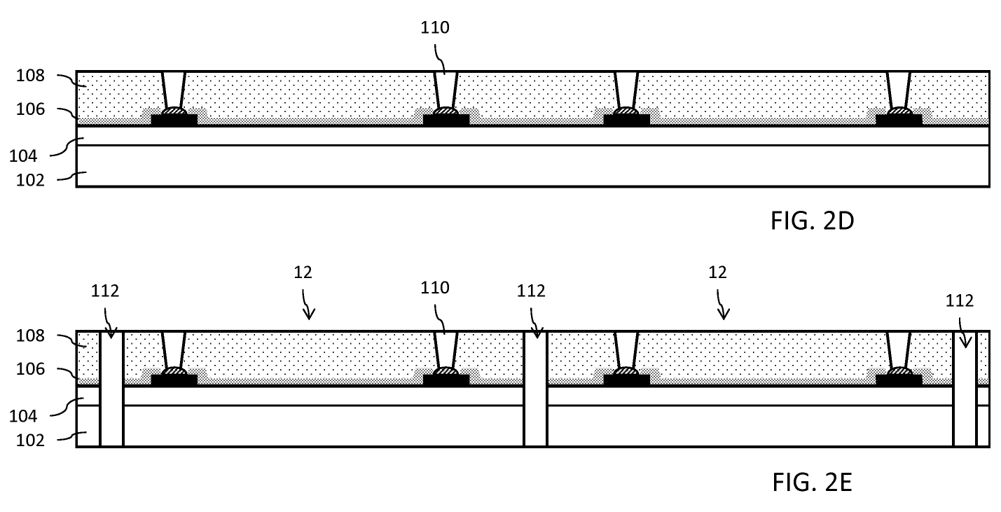

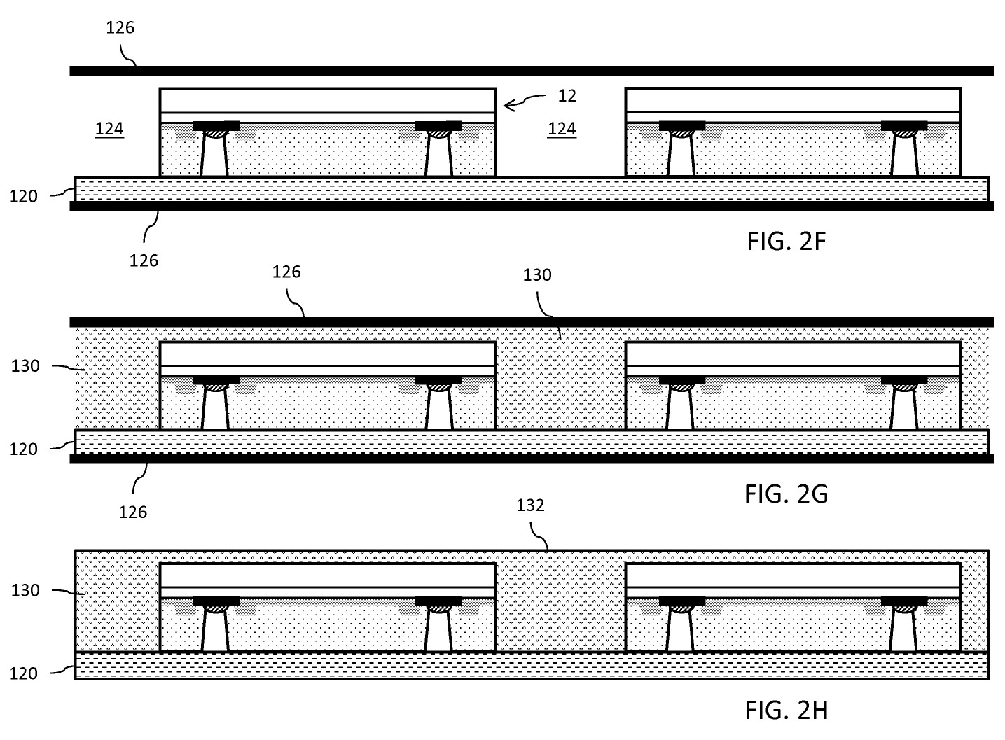

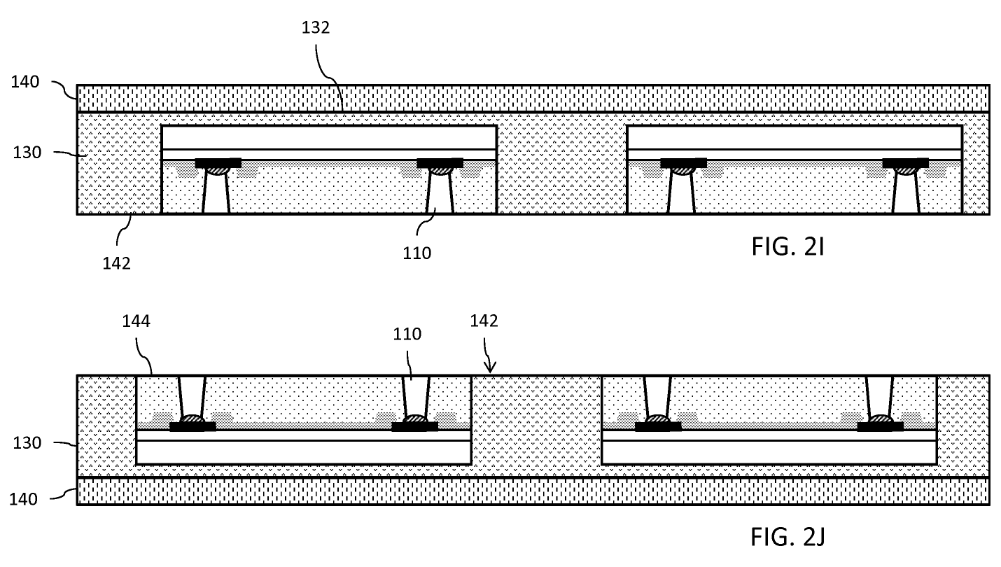

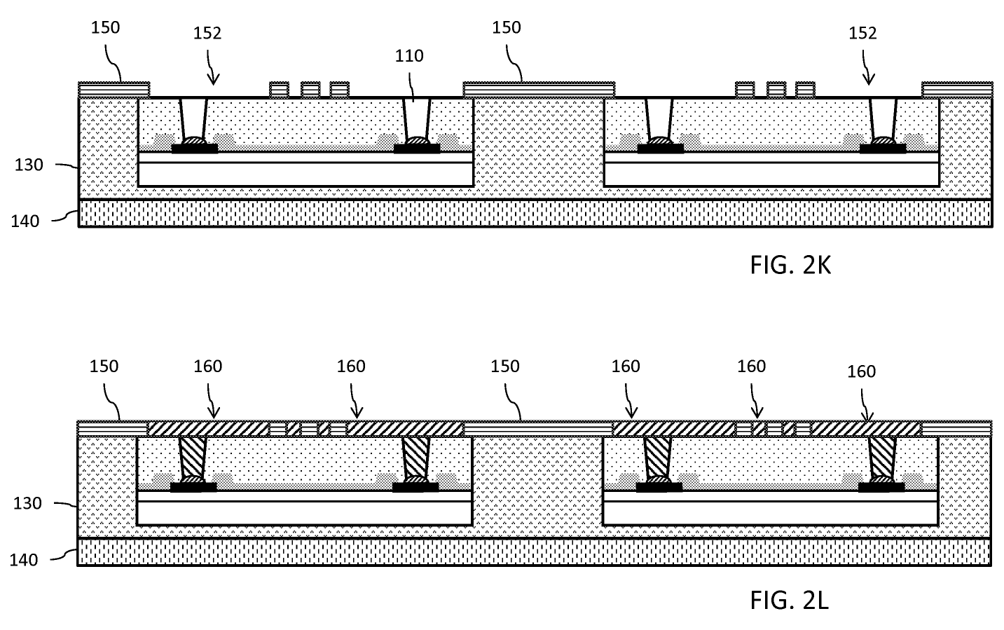

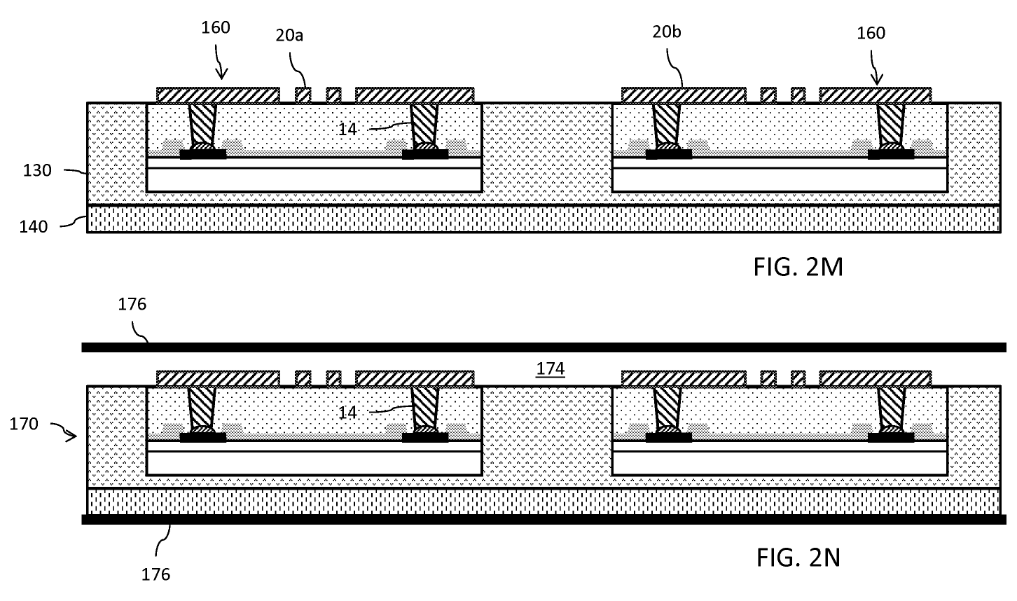

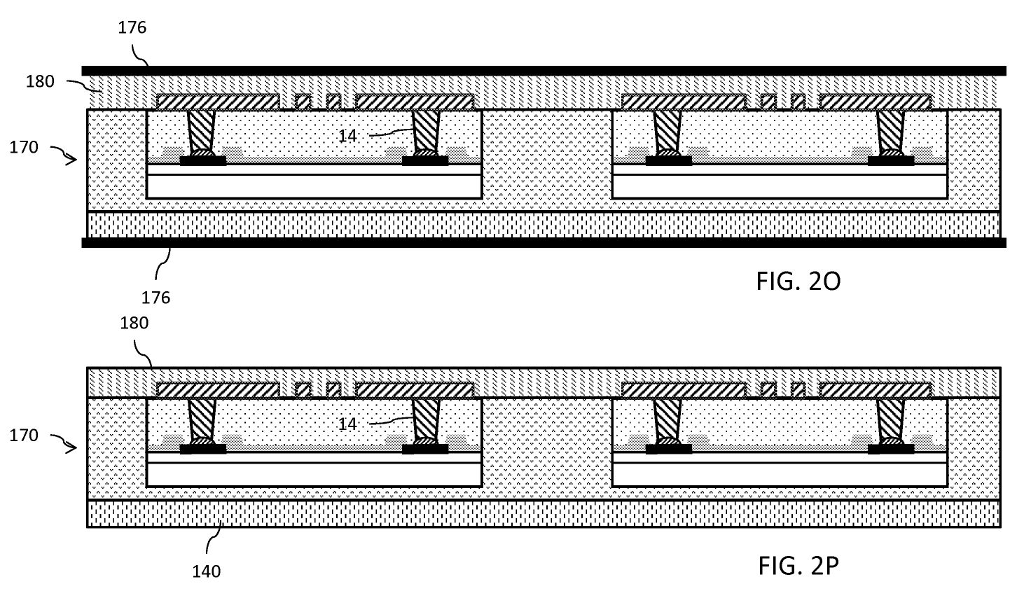

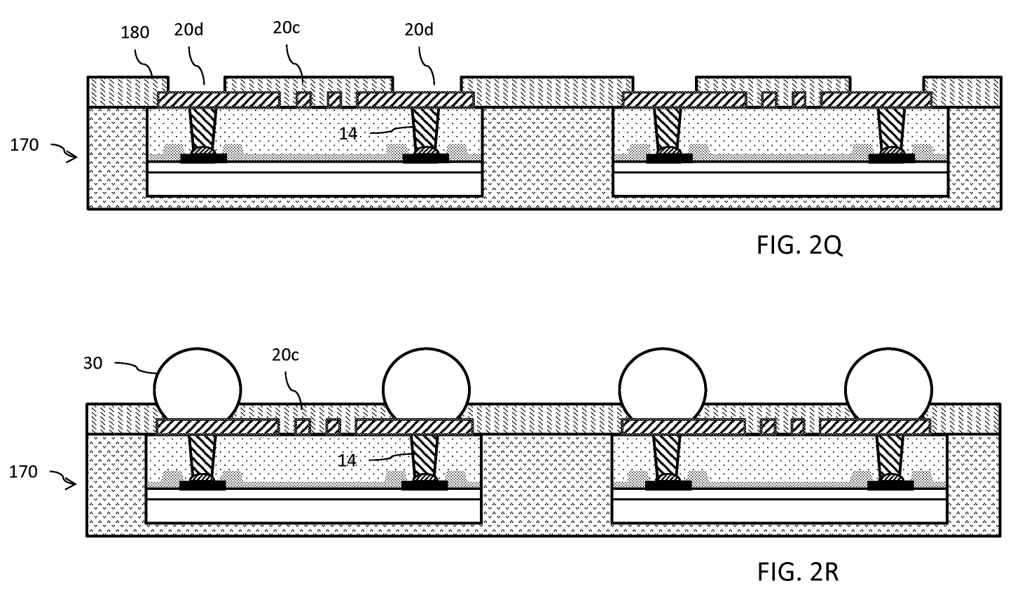

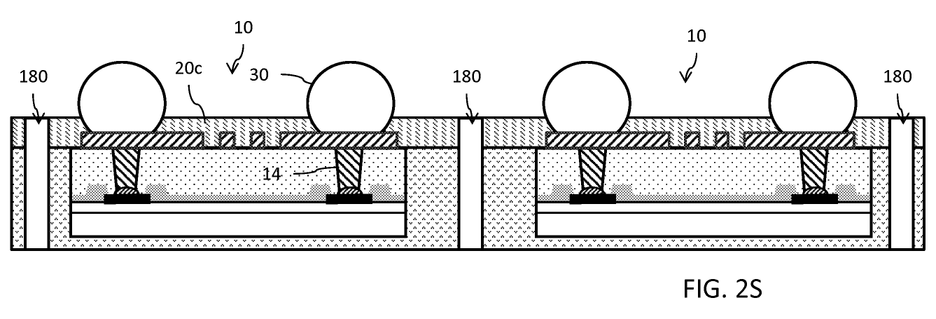

Reference is made to FIGS. 2A-2S which illustrate steps in process for forming the package shown in FIG. 1.

FIG. 2A – a wafer 100 includes a semiconductor, for example silicon, substrate 102 and an interconnection layer 104 with die pads 12c (the interconnection layer 104 including interconnection structures (lines, vias, etc., an example of which are illustrated in FIG. 2A, but otherwise omitted from illustration in the remaining figures for sake of clarity) for electrically connecting the die pads 12c to integrated circuitry within the substrate 102). A layer 106 of passivation material covers the upper surface of the interconnection layer 12b and partially covers the die pads 12c which are exposed at die pad openings. The wafer includes a plurality of integrated circuitry areas delimited from each other by scribe lines (the location of which, for example, is generally indicated by a vertical dotted line).

FIG. 2B – using an ink jet printing tool 120 for controlled dispensing of a conductive ink, an electrically conductive die pad protection layer 12e is printed in contact with an upper surface of each die pad 12c and positioned solely within the die pad openings in the die passivation layer 106 at each die pad 12c. The die pad protection layer 12e is made of a material comprising copper (Cu), gold (Au) or silver (Ag), or alloys thereof, and has a thickness in a range of 1 to 3 µm. The thickness of the die pad protection layer 12e is selected at an optimized value that will provide sufficient protection for the die pads 12c while still being able to be produced in the IC fabrication process without introducing a significant processing delay. Ink jet printing is exemplary of a process which can be used to quickly and accurately produce the die pad protection layer 12e at each opening. The die pad protection layer 12e effectively comprises a dot (or spot or drop) of conductive protective material printed on the die pad 12c at each opening in the die passivation layer 106. This dot of material can have any suitable shape and will generally conform in shape to the shape of the opening defined in the passivation layer 106 and should preferably be larger in area than the via contact area.

FIG. 2C – a dielectric film layer 108 (such as, for example, of the build-up film type known in the semiconductor manufacturing art) is installed to cover the wafer 100 (more specifically, covering the die passivation layer 12d). The wafer 100 covered by the dielectric film layer 108 is then processed in a laser drilling operation using a laser tool 130, or other suitable process, to open a plurality of via holes 110 extending through the dielectric film layer 108 to reach the upper surface of the die pad protection layer 12e. It will be noted that the power of the laser can be increased to improve the speed of completing the hole drilling process because the die pad protection layer 12e is placed to protect against damaging the die pad 12c. Furthermore, there is no need with the presence of the die pad protection layer 12e to perform the laser drilling operation in two or more steps having different laser power levels (for example, a prior art drilling process may use a first relatively higher laser drilling step to start the via opening followed by a second relatively lower laser drilling step to complete the via opening).

It will be noted that the die pad protection layer 12e functions to protect the die pads 12c from damage which could be caused by the laser drilling operation which opens the plurality of via holes 110. In an embodiment, the via holes 110 are left open, to be filled later in the manufacturing process. Alternatively, the via holes 110 may be filled with a conductive material (for example, copper) using a plating operation to form the vias 14.

FIG. 2D – a handle (not explicitly shown) is mounted to the frontside of the wafer 100 and a back side grinding or polishing operation is performed on the wafer to reduce the thickness of the substrate 102.

FIG. 2E – the thinned wafer 100 covered by the film layer 106 is then processed in a singulation operation by cutting 112 (for example, dicing) the wafer into a plurality of individual integrated circuit (IC) dies 12. The cutting may be performed by a sawing action taken along the scribe line locations between the locations of the integrated circuitry. The dicing of the wafer defines the substrate 12a, interconnect layer 12b, die passivation layer 12d and dielectric film layer 12f for each die 12.

FIG. 2F – plural IC dies 12 are mounted upper face down to a carrier panel 120. The panel 120 with the mounted IC dies 12 is then placed with a cavity 124 of a two part mold 126.

FIG. 2G – an encapsulation material 130 is injected into the cavity 124 and allowed to cure so as to laterally encapsulate each of the IC dies 12 as well as cover the back sides of the IC dies 12. This encapsulation material 130 provides the encapsulating body 16 of each package 10.

FIG. 2H – the laterally encapsulated plurality of IC dies 12 mounted to the panel 120 are removed from the mold 126. If necessary, a grinding operation can be performed at the back side 132 to ensure a planar back surface. The grinding operation may also be used to remove the excess encapsulation material 130 layer at the back surfaces of the IC dies 12 to control the thickness of the encapsulating body 16.

FIG. 2I – a further carrier panel 140 is the mounted to the back side 132 of the encapsulation material 130, and the carrier panel 120 is removed. This exposes the coplanar front side 142 of the laterally encapsulated plurality of IC dies 12 and exposes the open holes 110 (if present and not already filled by conductive material) in the dielectric film layer 12f.

FIG. 2J – a sputtering operation is then performed to deposit a thin barrier layer 144 on the front side 142 of the panel including on the side walls of the openings 110 and the upper surface of the die pad protection layer 12e. The barrier layer 144 may, for example, be made of a TiCu alloy material.

FIG. 2K – a mask layer 150 is then deposited on the panel over the barrier layer 144, and this mask layer 150 is patterned to define openings 152 at the vias 14 and locations where the electrically conductive lines 20a and package pads 20b of the redistribution layer 20 are to be formed.

FIG. 2L – a plating operation is then performed to plate a metal material 160 (for example, copper) to fill the openings 110 to form the vias 14 (if not already performed) and to fill the openings 152 to form the electrically conductive lines 20a and package pads 20b of the redistribution layer 20.

FIG. 2M – the mask layer 150 is then stripped and the portions of the barrier layer 144 not covered by the electrically conductive lines 20a and package pads 20b is removed by a selective etch.

FIG. 2N – the panel 170 is then placed with a cavity 174 of a two part mold 176.

FIG. 2O – an encapsulation material 180 is injected into the cavity 174 and allowed to cure so as to laterally encapsulate electrically conductive lines 20a and package pads 20b of the redistribution layer 20. This encapsulation material 180 provides the encapsulating body 20c of each package 10.

FIG. 2P – the encapsulated panel 170 is removed from the mold 176. If necessary, a grinding operation can be performed at the upper surface of the encapsulation material 180 to ensure a planar surface.

FIG. 2Q – the encapsulated panel 70 is then removed from the further carrier panel 140. A laser process and plasma etch is then performed to provide the openings 20d extending through the encapsulation material 180 of the encapsulating body 20c at the package pads 20b.

FIG. 2R – the solder balls 30 are then positioned at each opening 20d and a reflow is performed.

FIG. 2S – the encapsulated panel 70 is then processed in a singulation operation by cutting 180 (for example, dicing) the panel into a plurality of individual packages 10. The cutting may be performed by a sawing action taken along the dicing line locations between the locations of the encapsulated IC dies 12. One of the resulting packages 10 is shown in FIG. 1.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
providing a wafer including a plurality of integrated circuit areas, said wafer including, for each integrated circuit area, a plurality of electrically conductive die pads, and further including a passivation layer over the plurality of electrically conductive die pads;
forming a die pad opening extending through the passivation layer at each electrically conductive die pad of the plurality of electrically conductive die pads;
jet printing a conductive ink at each die pad opening to form a die pad protection layer covering an upper surface of each electrically conductive die pad of the plurality of electrically conductive die pads;
providing a film layer covering the passivation layer and the die pad protection layer at each electrically conductive die pad of the plurality of electrically conductive die pads; and
laser drilling a via opening through the film layer to reach the die pad protection layer at each electrically conductive die pad of the plurality of electrically conductive die pads.

2. The method of claim 1, further comprising filling each via opening with a conductive material to form a conductive via.

3. The method of claim 2, further comprising forming a redistribution layer over the film layer and the conductive vias.

4. The method of claim 3, wherein the redistribution layer includes electrically conductive lines and package pads electrically coupled to the conductive vias.

5. The method of claim 4, further comprising providing a solder ball at each package pad.

6. The method of claim 4, further comprising providing an encapsulation layer configured to encapsulate the electrically conductive lines and package pads of the redistribution layer.

7. The method of claim 1, wherein the conductive ink includes a copper material.

8. The method of claim 1, wherein the conductive ink includes a gold material.

9. The method of claim 1, wherein the conductive ink includes a silver material.

10. The method of claim 1, wherein the film layer is a build-up film.

11. The method of claim 1, further comprising singulating the wafer to form a plurality of IC dies.

12. An integrated circuit die made using the method of claim 11.

13. An integrated circuit package including the integrated circuit die of claim 12.

14. An integrated circuit die, comprising:
a semiconductor substrate with integrated circuitry;
an interconnection layer with a plurality of electrically conductive die pads electrically coupled to the integrated circuitry;
a die passivation layer covering an upper surface of the interconnection layer, said die passivation layer only partially covering each electrically conductive die pad of the plurality of electrically conductive die pads;
a dot of conductive ink at an upper surface of each electrically conductive die pad of the plurality of electrically conductive die pads, said dot forming a die pad protection layer within a die pad opening in the die passivation layer; and
a film layer covering the die passivation layer and the die pad protection layer over each electrically conductive die pad of the plurality of electrically conductive die pads, wherein the film layer includes via openings extending through the film layer to reach the die pad protection layer at each electrically conductive die pad of the plurality of electrically conductive die pads.

15. The integrated circuit die of claim 14, wherein the film layer is a build-up film.

16. The integrated circuit die of claim 14, wherein the conductive ink includes a copper material.

17. The integrated circuit die of claim 14, wherein the conductive ink includes a gold material.

18. The integrated circuit die of claim 14, wherein the conductive ink includes a silver material.

19. The integrated circuit die of claim 14, wherein each via opening is filled with a conductive material forming a conductive via.

20. An integrated circuit package including the integrated circuit die of claim 19.
